(19) United States
(12) Patent Application Publication
(10) Pub. No.: US 2022/0406975 A1
(43) Pub. Date: Dec. 22, 2022

(54) DISPLAY DEVICE AND METHOD OF MANUFACTURING THE SAME

(71) Applicant: Samsung Display Co., LTD., Yongin-si (KR)

(72) Inventors: Jun Young LEE, Seoul (KR); Si Joon SONG, Suwon-si (KR)

(73) Assignee: Samsung Display Co., LTD., Yongin-si (KR)

(21) Appl. No.: 17/729,474

(22) Filed: Apr. 26, 2022

(30) Foreign Application Priority Data
Jun. 17, 2021 (KR) 10-2021-0078616

(51) Int. Cl. H01L 33/56; H01L 33/00; H01L 27/15

(52) U.S. Cl. CPC H01L 33/56; H01L 33/005; H01L 27/156; H01L 2933/005

(57) ABSTRACT

A display device comprises a substrate including a first surface, a second surface opposite to the first surface, and a side surface extending from the first surface to the second surface, a film having an end attached to the first surface of the substrate and bent from the end to cover the side surface of the substrate, and a cover member including a first cover part disposed on the first surface of the substrate, and a second cover part disposed on the side surface of the substrate, wherein the film is disposed between the first surface of the substrate and the first cover part and between the side surface of the substrate and the second cover part, and the second cover part has an outwardly convex shape.

### CROSS-REFERENCE TO RELATED APPLICATION(S)

This application claims priority to and benefits of Korean Patent Application No. 10-2021-0078616 under 35 U.S.C. 119, filed on Jun. 17, 2021 in the Korean Intellectual Property Office, the entire contents of which are herein incorporated by reference.

### BACKGROUND

### 1. Technical Field

The disclosure relates to a display device and a method of manufacturing the same.

### 2. Description of the Related Art

As information society develops, demand for display devices to display images increases and diversifies. For example, display devices have been applied to various electronic devices such as smartphones, digital cameras, laptop computers, navigation devices, and smart televisions.

Display devices are devices that display images, and may include display panels such as organic light emitting display panels and liquid crystal display panels. Among display panels, a light emitting display panel may include a light emitting element such as a light emitting diode (LED). Examples of light emitting diodes include an organic light emitting diode (OLED) that uses an organic material as a light emitting material, an inorganic light emitting diode that uses an inorganic material as a light emitting material, and the like.

### SUMMARY

Aspects of the disclosure provide a display device that may be capable of improving aesthetics, reducing an amount of resin used in a frame area, and reusing the resin by minimizing the frame area.

However, aspects of the disclosure are not restricted to those set forth herein. The above and other aspects of the disclosure will become more apparent to one of ordinary skill in the art to which the disclosure pertains by referencing the detailed description of the disclosure given below.

According to an embodiment, a display device may include a substrate including a first surface, a second surface opposite to the first surface, and a side surface extending from the first surface to the second surface, a film having an end attached to the first surface of the substrate and bent from the end to cover the side surface of the substrate, and a cover member including a first cover part disposed on the first surface of the substrate, and a second cover part disposed on the side surface of the substrate, wherein the film may be disposed between the first surface of the substrate and the first cover part and between the side surface of the substrate and the second cover part, and the second cover part has an outwardly convex shape.

According to another embodiment, the first cover part may have a first thickness, and the second cover part may have a second thickness smaller than the first thickness.

According to another embodiment, the second cover part may be disposed on a side surface of the first cover part, and the first cover part and the second cover part may be integral with each other.

According to another embodiment, the second cover part may be disposed on a side surface of the first cover part, and the cover member may further include an interface disposed between the first cover part and the second cover part.

According to another embodiment, the display device may further include a filler disposed between the film and the side surface of the substrate.

According to another embodiment, the second cover part may be bisected in a thickness direction to include a first area and a second area that may be sequentially stacked on each other, and the first area may have a thickness greater than a thickness of the second area.

According to another embodiment, the display device may further include a display area displaying a screen, and a non-display area adjacent to the display area. The film and the cover member may be disposed in the non-display area.

According to another embodiment, the display device of claim 7, may further include pixels disposed in the display area. Each of the pixels may include an inorganic light emitting element.

According to another embodiment, a display device may include a substrate including a first surface, a second surface opposite to the first surface, and a side surface extending from the first surface to the second surface, a film having an end attached to the first surface of the substrate and bent from the end to cover the side surface of the substrate, and a cover member including a first cover part disposed on the first surface of the substrate, and a second cover part disposed on the side surface of the substrate, wherein the first cover part has a first thickness, and the second cover part has a second thickness smaller than the first thickness.

According to another embodiment, the second cover part may be disposed on a side surface of the first cover part, and the cover member may further include an interface disposed between the first cover part and the second cover part.

According to another embodiment, the second cover part may be bisected in a thickness direction to include a first area and a second area that may be sequentially stacked on each other, and the first area may have a thickness greater than a thickness of the second area.

According to still another embodiment, a method of manufacturing a display device may include bending a film attached to a first surface of a substrate toward a lower surface of the substrate along a side surface of the substrate, applying a first cover material layer onto the first surface of the substrate and the film, and applying a second cover material layer onto the side surface of the substrate and the film.

According to another embodiment, the method may further include, after the applying of the second cover material layer, curing the first cover material layer and the second cover material layer.

According to another embodiment, the curing of the first cover material layer and the second cover material layer may be performed by ultraviolet (UV) light.

According to another embodiment, the method may further include curing the first cover material layer, after the applying of the first cover material layer and before the applying of the second cover material layer, and

curing the second cover material layer, after the applying of the second cover material layer.

According to another embodiment, the curing of the first cover material layer may be performed by a first curing module, and the curing of the second cover material layer may be performed by a second curing module.

According to another embodiment, the first cover material layer may be applied by a first applying module, and the first applying module may move from a second side in a first direction to a first side in the first direction.

According to another embodiment, the second cover material layer may be applied by a second applying module, and the second applying module may move from the first side in the first direction to the second side in the first direction.

According to another embodiment, the method may further include, after the applying of the second cover material layer, curing the first cover material layer and the second cover material layer. The curing of the first cover material layer and the second cover material layer may be performed by a curing module, and the curing module may move from the first side in the first direction to the second side in the first direction.

According to another embodiment, the second cover material layer may be applied by a second applying module, and the second applying module may move from the first side in the first direction to the second side in the first direction.

With the display device according to an embodiment, an amount of resin used in the frame area of the display device may be reduced and the resin may be reused, such that a process cost may be reduced.

The effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to an embodiment;

FIG. 2 is a schematic plan view of the display device according to an embodiment;

FIG. 3 is a schematic cross-sectional view of a display area of a display panel according to an embodiment;

FIG. 4 is a schematic perspective view of a light emitting element according to an embodiment;

FIG. 5 is an enlarged schematic cross-sectional view of the display panel according to an embodiment;

FIG. 6 is a schematic cross-sectional view taken along line VI-VI′ of FIG. 1;

FIG. 7 is a schematic cross-sectional view taken along line VII-VII′ of FIG. 1;

FIGS. 8 to 10 are schematic views for describing a method of manufacturing a display device according to an embodiment;

FIGS. 11 and 12 are schematic views for describing a method of manufacturing a display device according to another embodiment;

FIGS. 13 and 14 are schematic views for describing a method of manufacturing a display device according to still another embodiment;

FIGS. 15 and 16 are schematic cross-sectional views of a display device according to another embodiment; and

FIGS. 17 and 18 are schematic cross-sectional views of a display device according to still another embodiment.

### DETAILED DESCRIPTION OF THE EMBODIMENTS

Hereinafter, embodiments will be described with reference to the attached drawings. Specific structural and functional descriptions of embodiments disclosed herein are only for illustrative purposes of the embodiments. The disclosure may be embodied in many different forms. Therefore, the embodiments are disclosed only for illustrative purposes and should not be construed as limiting the disclosure.

It will be understood that when an element is referred to as being related to another element such as being “in contact”, “coupled” or “connected” to another element, it can be directly in contact, coupled or connected to the other element or intervening elements may be present therebetween. In contrast, it should be understood that when an element is referred to as being related to another element such as being “in direct contact”, “directly coupled” or “directly connected” to another element, there may be no intervening elements present. Other expressions that explain the relationship between elements, such as “between,” “directly between,” “adjacent to,” or “directly adjacent to,” should be construed in the same way.

It will be understood that the terms “connected to” or “coupled to” may include a physical or electrical connection or coupling. Also, when an element is referred to as being “in contact” or “contacted” or the like to another element, the element may be in “electrical contact” or in “physical contact”.

Throughout the specification, the same reference numerals will refer to the same or like parts.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise.

The terms “and” and “or” may be used in the conjunctive or disjunctive sense and may be understood to be equivalent to “and/or.” As used herein, the term “and/or” includes any and all combinations of one or more of the associated listed items. For example, “A and/or B” may be understood to mean “A, B, or A and B.” In the specification and the claims, the phrase “at least one of” is intended to include the meaning of “at least one selected from the group of” for the purpose of its meaning and interpretation. For example, “at least one of A and B” may be understood to mean “A, B, or A and B.” It will be further understood that the terms “comprises”, “comprising,”, “has”, “having”, “includes” and/or “including” specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in one of the drawings is turned over, elements described as being on the “lower” side of other elements would then be oriented on “upper” sides of the other elements. The term “lower” can therefore encompass both an orientation of “lower” and “upper,” depending on the particular orientation of the drawing. Similarly, if the device in one of the drawings is turned over, elements described as “below” or “beneath” other elements would then be oriented “above” the other elements. The terms “below” or “beneath” can therefore encompass both an orientation of above and below.

“About”, “approximately”, “substantially”, and the like are inclusive of the stated value and mean within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. When an element is described as “not overlapping” or “to not overlap” another element, this may include that the elements are spaced apart from each other, offset from each other, or set aside from each other or any other suitable term as would be appreciated and understood by those of ordinary skill in the art.

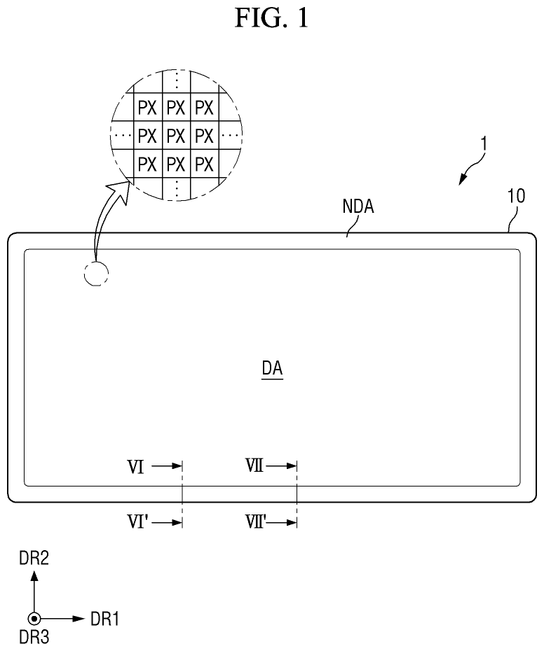

FIG. 1 is a schematic plan view of a display device according to an embodiment.

Referring to FIG. 1, a display device 1 may display a moving image or a still image. The term display device 1 may refer to all electronic devices that provide display screens. For example, televisions, laptop computers, monitors, billboards, Internet of Things (IoT) devices, mobile phones, smartphones, tablet personal computers (PCs), electronic watches, smartwatches, watch phones, head mounted displays, mobile communication terminals, electronic organizers, electronic books, portable multimedia players (PMPs), navigation devices, game machines, digital cameras, camcorders, and the like, that provide display screens may be included as the display device 1.

Hereinafter, a first direction DR1, a second direction DR2, and a third direction DR3 are defined in the drawings of an embodiment for describing the display device 1. The first direction DR1 and the second direction DR2 may be directions perpendicular to each other in a plane. The third direction DR3 may be a direction perpendicular to the plane in which the first direction DR1 and the second direction DR2 may be disposed (e.g., positioned). The third direction DR3 may be perpendicular to each of the first direction DR1 and the second direction DR2. In an embodiment for describing the display device 1, the third direction DR3 refers to a thickness direction of the display device 1.

The display device 1 may have a rectangular shape, in plan view, in which the first direction DR1 may be longer than the second direction DR2 and which may include long sides and short sides. A corner portion where the long side and the short side of the display device 1 meet in plan view may be right-angled, but is not limited thereto, and may have a rounded curved shape. The shape of the display device 1 in plan view is not limited to that described above, and may be other shapes such as a square shape, a quadrangular shape with rounded corners (e.g., vertices), a polygonal shape, and a circular shape.

A display surface of the display device 1 may be disposed on a side in the third direction DR3, which may be the thickness direction. In embodiments for describing the display device 1, unless otherwise stated, “upper portion” may be a side in the third direction DR3 and may refer to a display direction, and “upper surface” may refer to a surface facing a side in the third direction DR3. “Lower portion” may be another side in the third direction DR3 and may refer to a direction opposite to the display direction, and “lower surface” may refer to a surface facing another side in the third direction DR3. “Left”, “right”, “upper”, and “lower” may refer to directions when the display panel 1 is viewed in plan view. For example, “right side” may refer to a side in the first direction DR1, “left side” may refer to another side in the first direction DR1, “upper side” may refer to a side in the second direction DR2, and “lower side” may refer to another side in the second direction DR2.

The display device 1 may include a display panel 10 providing a display screen. Examples of the display panel 10 include an inorganic light emitting diode display panel, an organic light emitting display panel, a quantum dot light emitting display panel, a plasma display panel, a field emission display panel, and the like. Hereinafter, a case where an inorganic light emitting diode display panel may be applied as the display panel will be described by way of example, but the disclosure is not limited thereto, and the same technical idea may be applied to other display panels.

The display panel 10 may include a display area DA and a non-display area NDA. The display area DA may be an area in which a screen may be displayed, and the non-display area NDA may be an area in which a screen may not be displayed.

A shape of the display area DA may follow the shape of the display device 1. For example, the shape of the display area DA may have a rectangular shape in plan view, similar to the overall shape of the display device 1. The display area DA may occupy substantially the center of the display device 1.

The display area DA may include pixels PX. The pixels PX may be arranged in a matrix direction. A shape of each pixel PX may be a rectangular or square shape in plan view. However, the disclosure is not limited thereto, and the shape of each pixel PX may be a rhombic shape in which each side may be inclined with respect to a direction. The respective pixels PX may be alternately arranged in, e.g., a stripe type or a PenTile® type.

The non-display area NDA may be disposed around the display area DA. The non-display area NDA may completely or partially surround the display area DA. In an embodiment, the display area DA may have a rectangular shape, and the non-display area NDA may be disposed adjacent to four sides of the display area DA. The non-display area NDA may constitute a bezel of the display device 1. Wirings, circuit drivers, or a pad part on which an external device may be mounted, which may be included in the display device 1, may be disposed in the non-display area NDA.

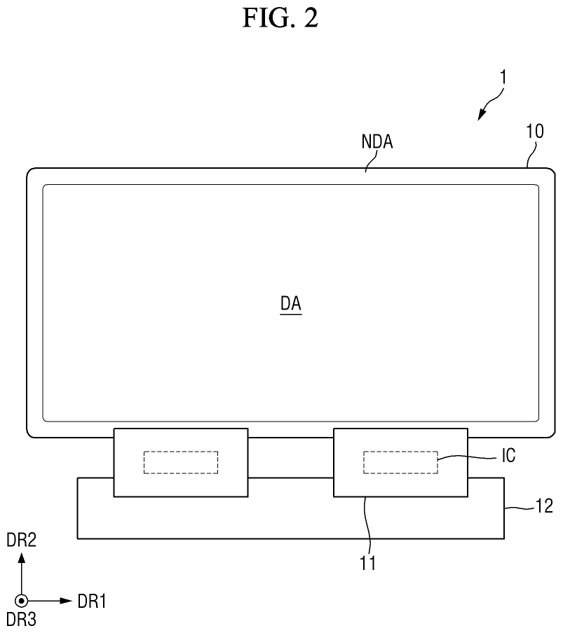

FIG. 2 is a schematic plan view of the display device according to an embodiment. FIG. 2 illustrates a state in which a connection film according to an embodiment is unfolded.

Referring to FIG. 2, the display device 1 may further include a driving chip IC, at least one connection film (or film) 11, and a circuit board 12.

The driving chip IC may be mounted on the connection film 11. However, the disclosure is not limited thereto, and the driving chip IC may also be mounted on the circuit board 12 or be mounted on the display panel 10. The driving chip IC may receive an external signal and generate a driving signal for driving the display panel 10.

The connection film 11 may serve to connect the display panel 10 and the circuit board 12 to each other. An end of the connection film 11 may be attached onto the display panel 10. An end of the connection film 11 may be attached onto the non-display area NDA of the display panel 10. The circuit board 12 may be attached to another end of the connection film 11. It has been illustrated in FIG. 2 that the connection film 11 may be disposed on only a side of the display panel 10 in the second direction DR2, but the disclosure is not limited thereto. The connection film 11 may also be disposed on another side of the display panel 10 in the second direction DR2 or be disposed on a side and/or another side of the display panel 10 in the first direction DR1. The connection film 11 may be bent toward a lower surface of the display panel 10.

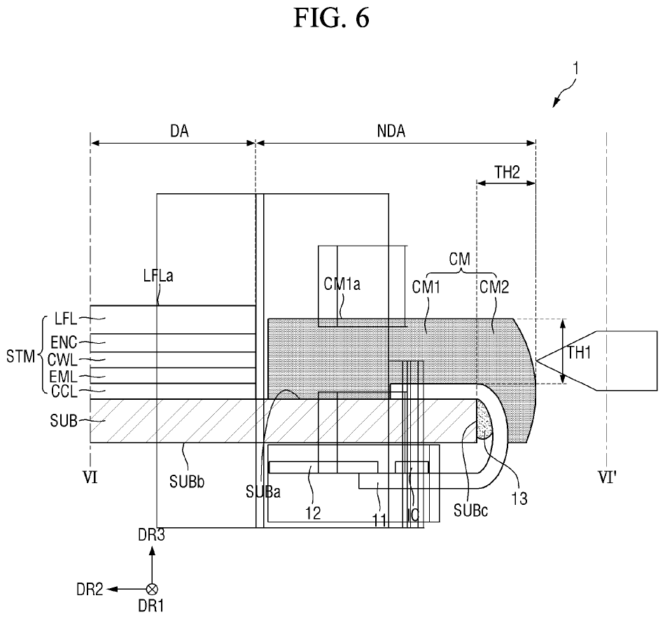

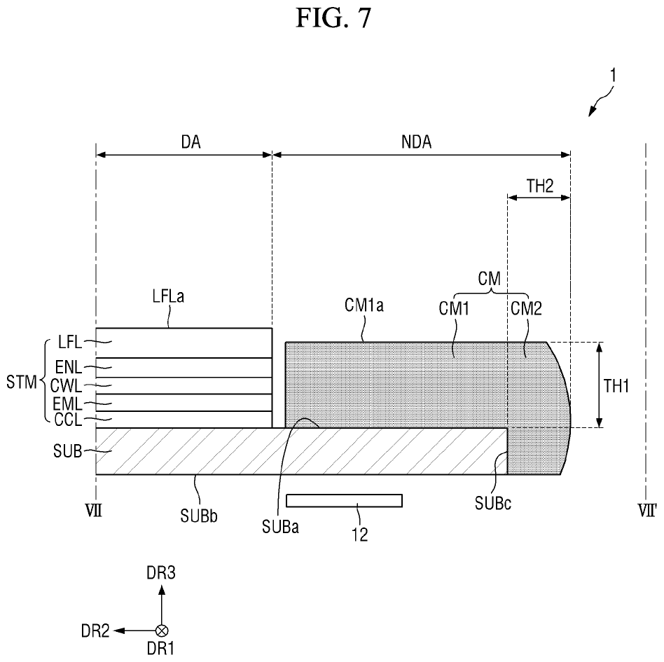

A cover member CM (see FIGS. 6 and 7) may be disposed on the non-display area NDA of the display panel 10 in which the connection film 11 may be positioned, and may cover the connection film 11, other wirings, and the like. Accordingly, it may be possible to suppress or prevent the connection film 11, other wirings, and the like, positioned in the corresponding area from being visible to a user, and a more immersive screen may be provided to the user. A detailed description for this will be provided later.

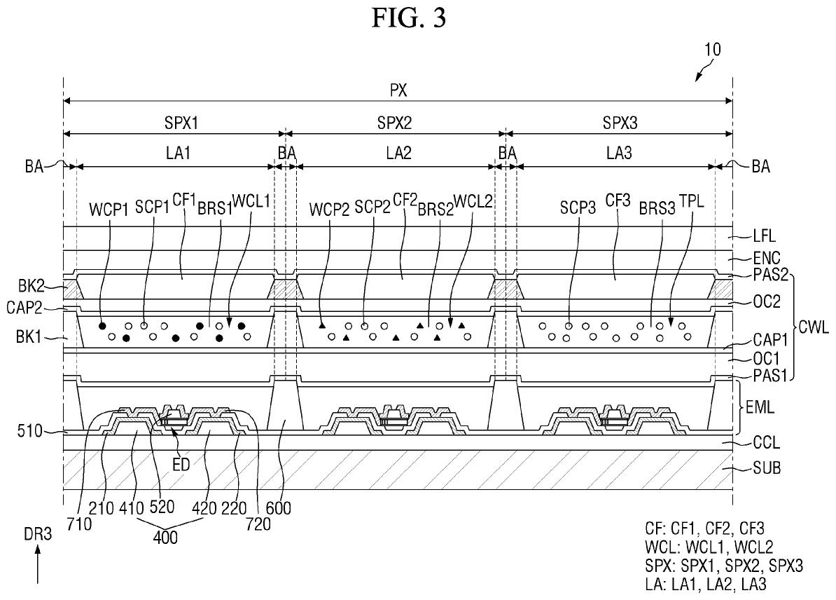

FIG. 3 is a schematic cross-sectional view of a display area of a display panel according to an embodiment.

Referring to FIG. 3, the display panel 10 may include a substrate SUB, a circuit layer CCL disposed on the substrate SUB, a light emitting element layer EML disposed on the circuit layer CCL, and a color control layer CWL, an encapsulation layer ENC, and an optical function layer LFL disposed on the light emitting element layer EML.

The substrate SUB may be an insulating substrate. The substrate SUB may be made of an insulating material such as glass, quartz, a polymer resin, or a combination thereof. The substrate SUB may be a rigid substrate, but may also be a flexible substrate capable of being bent, folded, or rolled.

The circuit layer CCL driving a pixel PX (or a sub-pixel SPX) may be disposed on a surface of the substrate SUB. The circuit layer CCL may include at least one transistor and the like to drive the light emitting element layer EML.

The light emitting element layer EML may be disposed on a surface of the circuit layer CCL. The light emitting element layer EML may include first banks 400, second banks 600, first electrodes 210, second electrodes 220, first contact electrodes 710, and second contact electrodes 720, light emitting elements ED, and insulating layers 510 and 520.

The first bank 400 may be disposed on the circuit layer CCL. The first bank 400 may be disposed in each of first to third light emission areas LA1, LA2, and LA3 of first to third sub-pixels SPX1, SPX2, and SPX3. The number of first banks 400 disposed in the first to third light emission areas LA1, LA2, and LA3 may be plural, and the first banks 400 may be disposed to be spaced apart from each other in the first direction DR1. In an embodiment, the first bank 400 disposed in the light emission area LA of each sub-pixel SPX may include a first sub-bank 410 and a second sub-bank 420.

The first electrode 210 may be disposed on the first sub-bank 410 to cover the first sub-bank 410. The second electrode 220 may be disposed on the second sub-bank 420 to cover the second sub-bank 420. The first electrode 210 and the second electrode 220 may be electrically insulated from each other.

A first insulating layer 510 may be disposed on the first electrode 210 and the second electrode 220, but may be disposed to expose at least portions of the first electrode 210 and the second electrode 220. The first insulating layer 510 may insulate the first electrode 210 and the second electrode 220 from each other while protecting the first electrode 210 and the second electrode 220. The first insulating layer 510 may prevent the light emitting element ED disposed on the first insulating layer 510 from being in direct contact with and being damaged by other members.

The second bank 600 may be disposed on the first insulating layer 510, and may include an opening exposing the first bank 400 and light emitting elements ED, which will be described later. The second bank 600 may be disposed at the boundary between the sub-pixels SPX to divide neighboring sub-pixels SPX. The second bank 600 may be disposed across the boundary between the neighboring sub-pixels SPX. The second bank 600 may serve to prevent ink from overflowing into adjacent sub-pixels SPX in an inkjet printing process in which the light emitting elements ED are provided in conjunction with dispersed ink.

The light emitting element ED may be disposed on the first insulating layer 510 between the first sub-bank 410 and the second sub-bank 420. The light emitting element ED may be disposed on the first insulating layer 510 between the first and second electrodes 210 and 220 so that ends thereof may be disposed on the first electrode 210 and the second electrode 220, respectively.

The light emitting elements ED may include an active layer having the same material to emit light of the same wavelength band or light of the same color. Light emitted from each of the first to third light emission areas LA1, LA2, and LA3 may have the same color. For example, the light emitting elements ED may emit light of a third color or blue light having a peak wavelength in the range of about 440 nm to about 480 nm. Therefore, the light emitting element layer EML may emit light of the third color or the blue light.

A second insulating layer 520 may be partially disposed on the light emitting element ED disposed between the first sub-bank 410 and the second sub-bank 420. The second insulating layer 520 may be disposed to partially surround an outer surface of the light emitting element ED. The second insulating layer 520 may be disposed on the light emitting element ED, but may expose ends of the light emitting element ED. The second insulating layer 520 may serve to protect the light emitting element ED and to fix the light emitting element ED in a process of manufacturing the display device 1.

The first contact electrode 710 may be disposed on the first electrode 210, and the second contact electrode 720 may be disposed on the second electrode 220. The first contact electrode 710 and the second contact electrode 720 may be electrically insulated from each other.

The first and second contact electrodes 710 and 720 may be in contact with the light emitting element ED and the first and second electrodes 210 and 220, respectively. Specifically, the first contact electrode 710 may be in contact with each of a partial area of the first electrode 210 exposed by the first insulating layer 510 and an end of the light emitting element ED exposed by the second insulating layer 520. The second contact electrode 720 may be in contact with each of a partial area of the second electrode 220 exposed by the first insulating layer 510 and another end of the light emitting element ED exposed by the second insulating layer 520.

An end of the light emitting element ED exposed by the second insulating layer 520 may be electrically connected to the first electrode 210 through the first contact electrode 710, and another end of the light emitting element ED exposed by the second insulating layer 520 may be electrically connected to the second electrode 220 through the second contact electrode 720.

The color control layer CWL may include a wavelength conversion layer WCL, a light transmission pattern TPL, and a color filter layer CF. The color control layer CWL may further include a first protective layer PAS1, a first planarization layer OC1, a first capping layer CAP1, a first light blocking member BK1, a second capping layer CAP2, and a second planarization layer OC2, a second light blocking member BK2, and a second protective layer PAS2.

The first protective layer PAS1 may be disposed on the light emitting element layer EML. The first protective layer PAS1 may serve to protect the light emitting element layer EML. The first protective layer PAS1 may prevent permeation of impurities such as moisture or air from the outside to prevent damage to the light emitting elements ED.

The first planarization layer OC1 may be disposed on the first protective layer PAS1. The first planarization layer OC1 may serve to planarize a step of an upper portion of the light emitting element layer EML. The first planarization layer OC1 may include an organic material. For example, the first planarization layer OC1 may include at least one of an acrylic resin, an epoxy resin, a phenolic resin, a polyamide resin, and a polyimide resin.

The first capping layer CAP1 may be disposed on the first planarization layer OC1. The first capping layer CAP1 may seal lower surfaces of the wavelength conversion layer WCL and the light transmission pattern TPL. The first capping layer CAP1 may include an inorganic material. For example, the first capping layer CAP1 may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

The first light blocking member BK1 may be disposed on the first capping layer CAP1. The first light blocking member BK1 may be disposed in a light blocking area BA. The first light blocking member BK1 may overlap the second bank 600 in the thickness direction (e.g., the third direction DR3) of the display device 1. The first light blocking member BK1 may block transmission of light. The first light blocking member BK1 may prevent the light from permeating between the first to third light emission areas EA1, EA2, and EA3 and mixing colors to improve a color reproduction rate. The first light blocking member BK1 may be formed in a lattice shape surrounding the first to third light emission areas LA1, LA2, and LA3 in plan view.

The first light blocking member BK1 may include an organic light blocking material and a liquid repellent component. Here, the liquid repellent component may be made of a fluorine-containing monomer or a fluorine-containing polymer, and specifically may include a fluorine-containing aliphatic polycarbonate. For example, the first light blocking member BK1 may be made of a black organic material including a liquid repellent component. The first light blocking member BK1 may be formed through coating and exposing processes or the like of an organic light blocking material including a liquid repellent component.

The wavelength conversion layer WCL and the light transmission pattern TPL may be disposed on the first capping layer CAP1 exposed by the first light blocking member BK1. The wavelength conversion layer WCL may convert a wavelength of the incident light, and the light transmission pattern TPL may pass the incident light therethrough while maintaining the wavelength of the incident light.

The wavelength conversion layer WCL or the light transmission pattern TPL may be disposed to be separated for each sub-pixel SPX. The wavelength conversion layer WCL or the light transmission pattern TPL may be disposed in the light emission area LA, and the wavelength conversion layers WCL and/or the light transmission patterns TPL disposed to neighbor each other may be spaced apart from each other by the first light blocking member BK1 disposed in the light blocking area BA.

The wavelength conversion layer WCL and the light transmission pattern TPL may be disposed on the first capping layer CPL1. In some embodiments, the wavelength conversion layer WCL and the light transmission pattern TPL may be formed by an inkjet method. However, the disclosure is not limited thereto, and the wavelength conversion layer WCL and the light transmission pattern TPL may be formed by applying a photosensitive material and exposing and developing the photosensitive material to pattern the photosensitive material. Hereinafter, a case where the wavelength conversion layer WCL and the light transmission pattern TPL may be formed by an inkjet method will be described by way of example.

The wavelength conversion layer WCL may be disposed in a sub-pixel SPX that needs to convert a wavelength of light incident from the light emitting element layer EML because the wavelength may be different from a color of the sub-pixel SPX. The light transmission pattern TPL may be disposed in a sub-pixel SPX of which a color may be the same as a wavelength of light incident from the light emitting element layer EML. An embodiment may be a case where light of a third color may be incident on the light emitting element layer EML of each sub-pixel SPX, and corresponds to an example in which the wavelength conversion layer WCL may be disposed in each of the first sub-pixel SPX1 and the second sub-pixel SPX2 and the light transmission pattern TPL may be disposed in the third sub-pixel SPX3.

In an embodiment, the wavelength conversion layer WCL may include a first wavelength conversion pattern WCL1 disposed in the first sub-pixel SPX1 and a second wavelength conversion pattern WCL2 disposed in the second sub-pixel SPX2.

The first wavelength conversion pattern WCL1 may be disposed in the first light emission area LA1 partitioned by the first light blocking member BK1 in the first sub-pixel SPX1. The first wavelength conversion pattern WCL1 may convert light having a wavelength of the third color incident from the light emitting element layer EML into light having a wavelength of a first color different from that of the third color, and emit the light having the wavelength of the first color. For example, the first wavelength conversion pattern WCL1 may convert blue light incident from the light emitting element layer EML into red light and emit the red light.

The first wavelength conversion pattern WCL1 may include a first base resin BRS1 and first wavelength conversion materials WCP1 dispersed in the first base resin BRS1. The first wavelength conversion pattern WCL1 may further include first scatterers SCP1 dispersed in the first base resin BRS1.

The second wavelength conversion pattern WCL2 may be disposed in the second light emission area LA2 partitioned by the first light blocking member BK1 in the second sub-pixel SPX2. The second wavelength conversion pattern WCL2 may convert light having a wavelength of the third color incident from the light emitting element layer EML into light having a wavelength of a second color different from that of the third color, and emit the light having the wavelength of the second color. For example, the second wavelength conversion pattern WCL2 may convert blue light incident from the light emitting element layer EML into green light and emit the green light.

The second wavelength conversion pattern WCL2 may include a second base resin BRS2 and second wavelength conversion materials WCP2 dispersed in the second base resin BRS2. The second wavelength conversion pattern WCL2 may further include second scatterers SCP2 dispersed in the second base resin BRS2.

The light transmission pattern TPL may be disposed in the third light emission area LA3 partitioned by the first light blocking member BK1 in the third sub-pixel SPX3. The light transmission pattern TPL may emit light having a wavelength of the third color incident from the light emitting element layer EML while maintaining the wavelength of the light. For example, the light transmission pattern TPL may transmit blue light incident from the light emitting element layer EML therethrough while maintaining a wavelength of the blue light.

The light transmission pattern TPL may include a third base resin BRS3. The light transmission pattern TPL may further include third scatterers SCP3 dispersed in the third base resin BRS3.

The first to third base resins BRS1, BRS2, and BRS3 may include a light-transmitting organic material. For example, the first to third base resins BRS1, BRS2, and BRS3 may include an epoxy-based resin, an acrylic resin, a cardo-based resin, an imide-based resin, or the like, or a combination thereof. All of the first to third base resins BRS1, BRS2, and BRS3 may be made of the same material, but are not limited thereto.

The first to third scatterers SCP1, SCP2, and SCP3 may have refractive indices different from those of the first to third base resins BRS1, BRS2, and BRS3. The first to third scatterers SCP1, SCP2, and SCP3 may include metal oxide particles or organic particles. Examples of metal oxide of the metal oxide particle may include titanium oxide (TiO₂), zirconium oxide (ZrO₂), aluminum oxide (Al₂O₃), indium oxide (In₂O₃), zinc oxide (ZnO), tin oxide (SnO₂), or the like, or a combination thereof, and examples of a material of the organic particle may include an acrylic resin, a urethane resin, or the like, or a combination thereof. All of the first to third scatterers SCP1, SCP2, and SCP3 may be made of the same material, but are not limited thereto.

The first wavelength conversion material WCP1 may be a material converting the third color into the first color, and the second wavelength conversion material WCP2 may be a material converting the third color into the second color. For example, the first wavelength conversion material WCP1 may be a material converting the blue light into the red light, and the second wavelength conversion material WCP2 may be a material converting the blue light into the green light. The first wavelength conversion material WCP1 and the second wavelength conversion material WCP2 may be quantum dots, quantum rods, phosphors, or the like. The quantum dot may include group IV nanocrystals, group II-VI compound nanocrystals, group III-V compound nanocrystals, group IV-VI compound nanocrystals, or a combination thereof

The second capping layer CAP2 may be disposed on the wavelength conversion layer WCL, the light transmission pattern TPL, and the first light blocking member BK1 to cover the wavelength conversion layer WCL, the light transmission pattern TPL, and the first light blocking member BK1. For example, the second capping layer CAP2 may seal the first wavelength conversion pattern WCL1, the second wavelength conversion pattern WCL2, the light transmission pattern TPL and the first light blocking member BK1 to prevent damage to or contamination of the first wavelength conversion pattern WCL1, the second wavelength conversion pattern WCL2, and the light transmission pattern TPL. The second capping layer CAP2 may be made of an inorganic material. The second capping layer CAP2 may be made of the same material as the first capping layer CAP1 or be made of the material exemplified in the first capping layer CAP1.

The second planarization layer OC2 may be disposed on the second capping layer CAP2 to planarize upper ends of the first and second wavelength conversion patterns WCL1 and WCL2 and the light transmission pattern TPL. The second planarization layer OC2 may include an organic material. For example, the second planarization layer OC2 may include at least one of an acrylic resin, an epoxy resin, a phenolic resin, a polyamide resin, and a polyimide resin.

The second light blocking member BK2 may be disposed on the second planarization layer OC2. The second light blocking member BK2 may be disposed in the light blocking area BA along the boundary between the sub-pixels SPX on the second planarization layer OC2. The second light blocking member BK2 may overlap the first light blocking member BK1 and/or the second bank 600 in the thickness direction (e.g., the third direction DR3). The second light blocking member BK2 may serve to not only block light emission, but also suppress external light reflection. The second light blocking member BK2 may be formed in a lattice shape surrounding the first to third light emission areas LA1, LA2, and LA3 in plan view.

The second light blocking member BK2 may include an organic material. In an embodiment, the second light blocking member BK2 may include a light absorbing material absorbing a visible ray wavelength band. As the second light blocking member BK2 may include the light absorbing material and may be disposed along the boundaries between the respective sub-pixels SPX, the second light blocking member BK2 may define the light emission areas LA: LA1, LA2, and LA3 of the respective sub-pixels SPX. For example, the second light blocking member BK2 may be a sub-pixel defining film defining the light emission areas LA of the respective sub-pixels SPX.

The color filter layer CF may be disposed on the second planarization layer OC2. The color filter layer CF may be disposed on a surface of the second planarization layer OC2 in areas partitioned by the second light blocking member BK2.

The color filter layer CF may include a first color filter CF1, a second color filter CF2, and a third color filter CF3.

The first color filter CF1 may be disposed in the first light emission area LA1 of the first sub-pixel SPX1, the second color filter CF2 may be disposed in the second light emission area LA2 of the second sub-pixel SPX2, and the third color filter CF3 may be disposed in the third light emission area LA3 of the third sub-pixel SPX3. The first to third color filters CF1, CF2, and CF3 may be surrounded by the second light blocking member BK2.

The first to third color filters CF1, CF2, and CF3 may include colorants such as dyes or pigments absorbing wavelengths other than corresponding color wavelengths. The first color filter CF1 may selectively transmit the light of the first color (e.g., the red light) and block or absorb the light of the second color (e.g., the green light) and the light of the third color (e.g., the blue light). The second color filter CF2 may selectively transmit the light of the second color (e.g., the green light) and block or absorb the light of the first color (e.g., the red light) and the light of the third color (e.g., the blue light). The third color filter CF3 may selectively transmit the light of the third color (e.g., the blue light) and block or absorb the light of the first color (e.g., the red light) and the light of the second color (e.g., the green light). For example, the first color filter CF1 may be a red color filter, the second color filter CF2 may be a green color filter, and the third color filter CF3 may be a blue color filter.

The first to third color filters CF1, CF2, and CF3 may absorb a portion of light introduced from the outside of the display device to reduce reflected light due to external light. Therefore, the first to third color filters CF1, CF2, and CF3 may prevent distortion of colors due to external light reflection.

The color filter layer CF may be disposed above the first and second wavelength conversion patterns WCL1 and WCL2 and the light transmission pattern TPL with the second planarization layer OC2 interposed therebetween, such that the display panel 10 may not require a separate substrate for the color filter layer CF. Therefore, a thickness of the display panel 10 may be relatively reduced.

The second protective layer PAS2 may be disposed on the color filter layer CF and the second light blocking member BK2 to cover the color filter layer CF and the second light blocking member BK2. The second protective layer PAS2 may serve to protect the color filter layer CF.

The encapsulation layer ENC may be disposed on the second protective layer PAS2. For example, the encapsulation layer ENC may include at least one inorganic film to prevent permeation of oxygen or moisture. The encapsulation layer ENC may include at least one organic film to protect the display panel 10 from foreign matters such as dust.

The optical function layer LFL may be disposed on the encapsulation layer ENC. The optical function layer LFL may be an anti-reflection layer preventing reflection of external light. The optical function layer LFL may be attached in a film form or may be formed by a coating method. However, the disclosure is not limited thereto, and an anti-fingerprint layer or the like may be disposed as the optical function layer LFL.

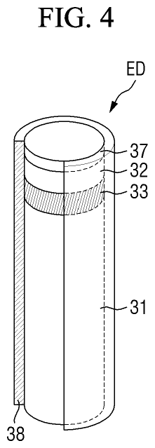

FIG. 4 is a schematic perspective view of a light emitting element according to an embodiment.

Referring to FIG. 4, the light emitting element ED may be a particle type element, and may have a rod or cylindrical shape having an aspect ratio. A length of the light emitting element ED may be greater than a diameter of the light emitting element ED, and the aspect ratio of the light emitting element ED may be about 1.2:1 to about 100:1, but the disclosure is not limited thereto.

The light emitting element ED may have a size of a nanometer scale (e.g., about 1 nm or more and less than about 1 μm) to a micrometer scale (e.g., about 1 μm or more and less than about 1 mm). In an embodiment, the light emitting element ED may have a size of a nanometer scale or have a size of a micrometer scale in both the length and the diameter. In some other embodiments, the diameter of the light emitting element ED may have a size of a nanometer scale, while the length of the light emitting element ED may have a size of a micrometer scale. In some embodiments, some of the light emitting elements ED have sizes of a nanometer scale in diameter and/or length, while the others of the light emitting elements ED may have a size of a micrometer scale in diameter and/or length.

The light emitting element ED may include an inorganic light emitting diode. The inorganic light emitting diode may include semiconductor layers. For example, the inorganic light emitting diode may include a first conductivity-type (e.g., n-type) semiconductor layer, a second conductivity-type (e.g., p-type) semiconductor layer, and an active semiconductor layer interposed between the first conductivity-type semiconductor layer and the second conductivity-type semiconductor layer. The active semiconductor layer may receive holes and electrons from the first conductivity-type semiconductor layer and the second conductivity-type semiconductor layer, respectively, and the holes and the electrons reaching the active semiconductor layer may be combined with each other to emit light.

In an embodiment, the above-described semiconductor layers may be sequentially stacked on each other along a length direction of the light emitting element ED. The light emitting element ED may include a first semiconductor layer 31, an element active layer 33, and a second semiconductor layer 32 that may be sequentially stacked on each other in the length direction, as illustrated in FIG. 4 The first semiconductor layer 31, the element active layer 33, and the second semiconductor layer 32 may be the above-described first conductivity-type semiconductor layer, active semiconductor layer, and second conductivity-type semiconductor layer, respectively.

The first semiconductor layer 31 may be doped with a first conductivity-type dopant. The first conductivity-type dopant may be Si, Ge, Sn, or the like, or a combination thereof. In an embodiment, the first semiconductor layer 31 may be made of n-GaN doped with n-type Si.

The second semiconductor layer 32 may be disposed to be spaced apart from the first semiconductor layer 31 with the element active layer 33 interposed therebetween. The second semiconductor layer 32 may be doped with a second conductivity-type dopant such as Mg, Zn, Ca, Se, Ba, or a combination thereof. In an embodiment, the second semiconductor layer 32 may be made of p-GaN doped with p-type Mg.

The element active layer 33 may include a material having a single or multiple quantum well structure. As described above, the element active layer 33 may emit light by a combination of electron-hole pairs according to an electrical signal applied through the first semiconductor layer 31 and the second semiconductor layer 32.

In some embodiments, the element active layer 33 may have a structure in which semiconductor materials having large band gap energy and semiconductor materials having small band gap energy may be alternately stacked on each other, and may include other Group III to Group V semiconductor materials depending on a wavelength band of emitted light.

The light emitted from the element active layer 33 may be emitted not only to outer surfaces of the light emitting element ED in the length direction, but also to both sides of the light emitting element ED. For example, an emission direction of the light from the element active layer 33 is not limited to one direction.

The light emitting element ED may further include an element electrode layer 37 disposed on the second semiconductor layer 32. The element electrode layer 37 may be in contact with the second semiconductor layer 32. The element electrode layer 37 may be an ohmic contact electrode, but is not limited thereto, and may be a Schottky contact electrode.

The element electrode layer 37 may be disposed between the second semiconductor layer 32 and the contact electrodes 710 and 720 to serve to reduce resistance, in case that ends of the light emitting element ED and the contact electrodes 710 and 720 may be electrically connected to each other in order to apply an electrical signal to the first semiconductor layer 31 and the second semiconductor layer 32. The element electrode layer 37 may include at least one of include aluminum (Al), titanium (Ti), indium (In), gold (Au), silver (Ag), indium tin oxide (ITO), indium zinc oxide (IZO), and indium tin zinc oxide (ITZO). The element electrode layer 37 may include an n-type or p-type doped semiconductor material.

The light emitting element ED may further include an element insulating film 38 surrounding outer peripheral surfaces of the first semiconductor layer 31, the second semiconductor layer 32, the element active layer 33, and/or the element electrode layer 37. The element insulating film 38 may be disposed to surround at least an outer surface of the element active layer 33, and may extend in a direction in which the light emitting element ED extends. The element insulating film 38 may serve to protect the first semiconductor layer 31, the second semiconductor layer 32, the element active layer 33, and the element electrode layer 37. The element insulating film 38 may be made of materials having insulating properties to prevent an electrical short-circuit that may occur in case that the element active layer 33 is in direct contact with an electrode through which an electrical signal may be transmitted to the light emitting element ED. The element insulating film 38 protects the outer peripheral surfaces of the first and second semiconductor layers 31 and 32 as well as the element active layer 33, and may thus prevent a decrease in luminous efficiency.

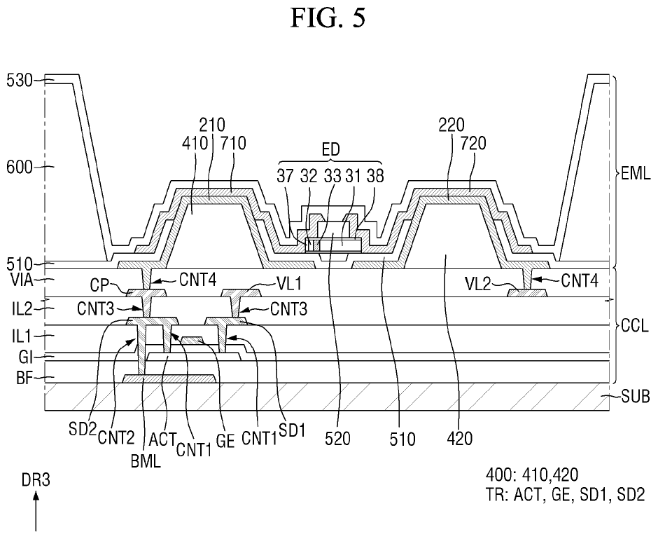

FIG. 5 is an enlarged schematic cross-sectional view of the display panel according to an embodiment.

Referring to FIG. 5, the circuit layer CCL may be disposed on the substrate SUB. The circuit layer CCL according to an embodiment may include a lower metal layer BML, a buffer layer BF, a semiconductor layer, conductive layers, and insulating films.

The lower metal layer BML may be disposed on the substrate SUB. The lower metal layer BML may be a light blocking layer serving to protect an active material layer ACT of a transistor TR from external light. The lower metal layer BML may include a material blocking light. For example, the lower metal layer BML may be formed of an opaque metal material blocking transmission of the light.

The lower metal layer BML, may have a patterned shape. The lower metal layer BML may be disposed to cover at least a channel region of the active material layer ACT of the transistor TR, and further, may be disposed to cover the entire active material layer ACT of the transistor TR, below the active material layer ACT of the transistor TR. However, the disclosure is not limited thereto, and the lower metal layer BML may be omitted.

The buffer layer BF may be disposed on the lower metal layer BML. The buffer layer BF may be disposed to cover the entire surface of the substrate SUB on which the lower metal layer BML may be disposed. The buffer layer BF may serve to protect the transistor TR from moisture permeating through the substrate SUB vulnerable to moisture permeation. The buffer layer BF may include inorganic layers that may be alternately stacked on each other. For example, the buffer layer BF may be formed as a multilayer in which inorganic layers including at least one of silicon oxide (SiOx), silicon nitride (SiNx), and silicon oxynitride (SiOxNy) may be alternately stacked on each other.

The semiconductor layer may be disposed on the buffer layer BF. The semiconductor layer may include the active material layer ACT of the transistor TR. The active material layer ACT of the transistor TR may be disposed to overlap the lower metal layer BML.

The semiconductor layer may include polycrystalline silicon, single crystal silicon, an oxide semiconductor, or the like, or a combination thereof. In an embodiment, in case that the semiconductor layer includes the polycrystalline silicon, the polycrystalline silicon may be formed by crystallizing amorphous silicon. In case that the semiconductor layer includes the polycrystalline silicon, the active material layer ACT of the transistor TR may include doped regions doped with impurities and channel regions between the doped regions. In another embodiment, the semiconductor layer may include an oxide semiconductor. The oxide semiconductor may be, for example, indium tin oxide (ITO), indium zinc oxide (IZO), indium gallium oxide (IGO), indium zinc tin Oxide (IZTO), indium gallium zinc oxide (IGZO), indium gallium tin oxide (IGTO), indium gallium zinc tin oxide (IGZTO), or the like, or a combination thereof.

A gate insulating film GI may be disposed on the semiconductor layer. The gate insulating film GI may function as a gate insulating film of the transistor TR. The gate insulating film GI may be formed as an inorganic layer including an inorganic material, for example, silicon oxide (SiOx), silicon nitride (SiNx), silicon oxynitride (SiOxNy), or a combination thereof, or may be formed in a structure in which such inorganic layers may be stacked on each other.

A first conductive layer may be disposed on the gate insulating film GI. The first conductive layer may include a gate electrode GE of the transistor TR. The gate electrode GE may be disposed to overlap the channel region of the active material layer ACT in the third direction DR3.

The first conductive layer may be formed as a single layer or multiple layers made of at least one of molybdenum (Mo), aluminum (Al), chromium (Cr), gold (Au), titanium (Ti), nickel (Ni), neodymium (Nd), and copper (Cu), or alloys thereof. However, the disclosure is not limited thereto.

An interlayer insulating film IL1 may be disposed on the first conductive layer. The interlayer insulating film IL1 may be disposed to cover the first conductive layer. The interlayer insulating film IL1 may include an inorganic insulating material such as silicon oxide (SiOx), silicon nitride (SiNx), silicon oxynitride (SiOxNy), or a combination thereof.

A second conductive layer may be disposed on the interlayer insulating film ILL The second conductive layer may include a drain electrode SD1 and a source electrode SD2 of the transistor TR. Although not illustrated in the drawings, the second conductive layer may further include a data line.

The drain electrode SD1 and the source electrode SD2 of the transistor TR may be electrically connected to end regions of the active material layer ACT of the transistor TR (e.g., respective doped regions of the active material layer ACT of the transistor TR), respectively, through first contact holes CNT1 penetrating through the interlayer insulating film IL1 and the gate insulating film GI. The source electrode SD2 of the transistor TR may be electrically connected to the lower metal layer BML through a second contact hole CNT2 penetrating through the interlayer insulating film ILL the gate insulating film GI, and the buffer layer BF.

The second conductive layer may be formed as a single layer or multiple layers made of at least one of molybdenum (Mo), aluminum (Al), chromium (Cr), gold (Au), titanium (Ti), nickel (Ni), neodymium (Nd), and copper (Cu), or alloys thereof. However, the disclosure is not limited thereto.

A passivation layer IL2 may be disposed on the second conductive layer. The passivation layer IL2 serves to cover and protect the second conductive layer. The passivation layer IL2 may include an inorganic insulating material such as silicon oxide (SiOx), silicon nitride (SiNx), silicon oxynitride (SiOxNy), or a combination thereof.

A third conductive layer may be disposed on the passivation layer IL2. The third conductive layer may include a first power line VL1, a second power line VL2, and a first conductive pattern CP.

A high potential voltage (e.g., a first source voltage) may be supplied to the first power line VL1, and a low potential voltage (e.g., a second source voltage) lower than the high potential voltage (first source voltage) supplied to the first power line VL1 may be supplied to the second power line VL2.

The first power line VL1 may be electrically connected to the drain electrode SD1 of the transistor TR. The first power line VL1 may be electrically connected to the drain electrode SD1 of the transistor TR through a third contact hole CNT3 penetrating through the passivation layer IL2.

The second power line VL2 may be electrically connected to the second electrode 220 so as to supply the low potential voltage (second source voltage) to the second electrode 220. The second power line VL2 may be electrically connected to the second electrode 220 through a fourth contact hole CNT4 to be described later to transfer the second source voltage to the second electrode 220. An alignment signal necessary for aligning the light emitting elements ED may be applied to the second power line VL2 in a process of manufacturing the display device 1.

The first conductive pattern CP may be electrically connected to the source electrode SD2 of the transistor TR through a third contact hole CNT3 penetrating through the passivation layer IL2. The first conductive pattern CP may be electrically connected to the first electrode 210 through a fourth contact hole CNT4 to be described later to transfer the first source voltage applied from the first power line VL1 to the first electrode 210.

The third conductive layer may be formed as a single layer or multiple layers made of at least one of molybdenum (Mo), aluminum (Al), chromium (Cr), gold (Au), titanium (Ti), nickel (Ni), neodymium (Nd), and copper (Cu), or alloys thereof. However, the disclosure is not limited thereto.

A via layer VIA may be disposed on the third conductive layer. The via layer VIA may be disposed on the passivation layer IL2 on which the third conductive layer may be disposed. The via layer VIA may serve to planarize a surface. The via layer VIA may include an organic insulating material, for example, an organic material such as polyimide (PI).

Referring to FIGS. 4 and 5, the light emitting element layer EML may be disposed on the via layer VIA of the circuit layer CCL. The light emitting element layer may include the light emitting elements ED, the first bank 400, the second bank 600, the first and second electrodes 210 and 220, the first and second contact electrodes 710 and 720, and insulating layers 510, 520, and 530.

The first bank 400 may be disposed on the via layer VIA. The first bank 400 may include the first sub-bank 410 and the second sub-bank 420. The first sub-bank 410 and the second sub-bank 420 may be disposed to be spaced apart from each other and face each other in the first direction DR1. A space formed by spacing the first sub-bank 410 and the second sub-bank 420 apart from each other may provide an area in which the light emitting elements ED may be disposed.

The first bank 400 may have a structure in which at least a portion thereof protrudes upward (e.g., toward a side in the third direction DR3) with respect to an upper surface of the via layer VIA. The protruding portion of the first bank 400 may have inclined side surfaces.

The first bank 400 may have the inclined surfaces to serve to change an advancing direction of light emitted from the light emitting element ED and advancing toward the side surfaces of the first bank 400 into an upward direction (e.g., a display direction). For example, the first bank 400 may provide a space in which the light emitting element ED may be disposed and also serve as a reflective partition wall (e.g., bank) changing the advancing direction of the light emitted from the light emitting element ED into the display direction.

It has been illustrated in the drawings that the side surfaces of the first bank 400 may be inclined in a linear shape, but the disclosure is not limited thereto. For example, the side surfaces (e.g., outer surfaces) of the first bank 400 may have a curved semicircular or semielliptical shape. In an embodiment, the first bank 400 may include an organic insulating material such as polyimide (PI), but is not limited thereto.

The first electrode 210 and the second electrode 220 may be disposed on the first bank 400 and the via layer VIA exposed by the first bank 400. Specifically, the first electrode 210 may be disposed on the first sub-bank 410, and the second electrode 220 may be disposed on the second sub-bank 420.

The first electrode 210 may be disposed on the first sub-bank 410 to cover an outer surface of the first sub-bank 410. The first electrode 210 may extend outward from side surfaces of the first sub-bank 410 to be partially disposed on the upper surface of the via layer VIA exposed by the first sub-bank 410 and the second sub-bank 420 in an area between the first sub-bank 410 and the second sub-bank 420.

The first electrode 210 may be in contact with the first conductive pattern CP through the fourth contact hole CNT4 penetrating through the via layer VIA. The first electrode 210 may be electrically connected to the transistor TR through the first conductive pattern CP.

The second electrode 220 may be disposed on the second sub-bank 420 to cover an outer surface of the second sub-bank 420. The second electrode 220 may extend outward from side surfaces of the second sub-bank 420 to be partially disposed on the upper surface of the via layer VIA exposed by the first sub-bank 410 and the second sub-bank 420 in the area between the first sub-bank 410 and the second sub-bank 420.

The second electrode 220 may be in contact with the second power line VL2 through the fourth contact hole CNT4 penetrating through the via layer VIA. The second electrode 220 may be electrically connected to the second power line VL2 through the fourth contact hole CNT4.

The first electrode 210 and the second electrode 220 may be disposed to be spaced apart from each other in the first direction DR1 so as to expose at least a portion of the via layer VIA in the area between the first sub-bank 410 and the second sub-bank 420.

The first and second electrodes 210 and 220 may be electrically connected to the light emitting elements ED, respectively, and a voltage may be applied to the first and second electrodes 210 and 220 so that the light emitting elements ED emit light. For example, the first and second electrodes 210 and 220 may be electrically connected to the light emitting element ED disposed between the first and second electrodes 210 and 220 through first and second contact electrodes 710 and 720 to be described later, and electrical signals applied to the first and second electrodes 210 and 220 may be transferred to the light emitting element ED through the first and second contact electrodes 710 and 720.

The first and second electrodes 210 and 220 may include a transparent conductive material. As an example, each of the first and second electrodes 210 and 220 may include a material such as indium tin oxide (ITO), indium zinc oxide (IZO), indium tin zinc oxide (ITZO), or a combination thereof, but is not limited thereto. In some other embodiments, the first and second electrodes 210 and 220 may include a conductive material having high reflectivity. For example, the first and second electrodes 210 and 220 may include a metal such as silver (Ag), copper (Cu), aluminum (Al), or a combination thereof as the material having the high reflectivity. The first and second electrodes 210 and 220 may reflect the light emitted from the light emitting element ED and advancing to the side surfaces of each first bank 400 so as to advance the light in the display direction. The disclosure is not limited thereto, and the first and second electrodes 210 and 220 may have a structure in which one or more layers made of the transparent conductive material and one or more layers made of the metal having the high reflectivity may be stacked on each other or may be formed as one layer including the transparent conductive material and the metal having the high reflectivity. In an embodiment, the first and second electrodes 210 and 220 may have a stacked structure such as ITO/silver (Ag)/ITO, ITO/Ag/IZO, or ITO/Ag/ITZO/IZO, or may be formed of an alloy including aluminum (Al), nickel (Ni), lanthanum (La), and the like.

The first insulating layer 510 may be disposed on the first and second electrodes 210 and 220. The first insulating layer 510 may be disposed on the first electrode 210 and the second electrode 220, but may be disposed to expose at least portions of the first electrode 210 and the second electrode 220. The first insulating layer 510 may be entirely formed on a surface of the substrate SUB including an area between the first electrode 210 and the second electrode 220, but may expose portions of the first electrode 210 and the second electrode 220.

The first insulating layer 510 may insulate the first electrode 210 and the second electrode 220 from each other while protecting the first electrode 210 and the second electrode 220. The first insulating layer 510 may prevent the light emitting element ED disposed on the first insulating layer 510 from being in direct contact with and being damaged by other members.

The second bank 600 may be formed to have a greater height than the first bank 400. The second bank 600 may serve to prevent ink from overflowing into adjacent pixels in an inkjet printing process for aligning the light emitting elements ED in the process of manufacturing the display device 1. In an embodiment, the second bank 600 may include an organic insulating material such as polyimide (PI), but is not limited thereto.

The light emitting element ED may be disposed on the first insulating layer 510 between the first and second electrodes 210 and 220 so that an end thereof may be disposed on the first electrode 210 and another end thereof may be disposed on the second electrode 220.

The light emitting element ED may have a shape in which it extends in a direction. An extension direction of the light emitting element ED may be substantially parallel to a surface of the substrate SUB, but is not limited thereto. In the light emitting element ED, in a cross section crossing ends of the light emitting element ED, the first semiconductor layer 31, the element active layer 33, the second semiconductor layer 32, and the element electrode layer 37 may be sequentially formed in a direction parallel to a surface of the substrate SUB.

The second insulating layer 520 may be partially disposed on the light emitting element ED. The second insulating layer 520 may be disposed on the light emitting element ED disposed between the first electrode 210 and the second electrode 220, but may expose ends of the light emitting element ED. The second insulating layer 520 may be disposed to partially surround an outer surface of the light emitting element ED. The second insulating layer 520 may serve to protect the light emitting element ED and to fix the light emitting element ED in the process of manufacturing the display device 1.

The first and second contact electrodes 710 and 720 may be disposed on the second insulating layer 520. The first contact electrode 710 and the second contact electrode 720 may be disposed to be spaced apart from each other and face each other in the first direction DR1. The first and second contact electrodes 710 and 720 may be disposed to be spaced apart from each other in the first direction DR1 on the second insulating layer 520.

The first contact electrode 710 may be disposed on the first electrode 210. The first contact electrode 710 may be in contact with the first electrode 210 exposed by the first insulating layer 510, and be in contact with an end of the light emitting element ED exposed by the second insulating layer 520. The first contact electrode 710 may be in contact with an end of the light emitting element ED and the first electrode 210 to serve to electrically connect the light emitting element ED and the first electrode 210 to each other.

The second contact electrode 720 may be disposed on the second electrode 220. The second contact electrode 720 may be in contact with the second electrode 220 exposed by the first insulating layer 510, and be in contact with another end of the light emitting element ED exposed by the second insulating layer 520. The second contact electrode 720 may be in contact with another end of the light emitting element ED and the second electrode 220 to serve to electrically connect the light emitting element ED and the second electrode 220 to each other.

For example, an end of the light emitting element ED exposed by the second insulating layer 520 may be electrically connected to the first electrode 210 through the first contact electrode 710, and another end of the light emitting element ED exposed by the second insulating layer 520 may be electrically connected to the second electrode 220 through the second contact electrode 720.

The first and second contact electrodes 710 and 720 may include a conductive material. For example, the first and second contact electrodes 710 and 720 may include ITO, IZO, ITZO, aluminum (Al), or the like, or a combination thereof. The first and second contact electrodes 710 and 720 may include a transparent conductive material, but are not limited thereto.

A third insulating layer 530 may be entirely disposed on the substrate SUB. The third insulating layer 530 may serve to protect members disposed on the substrate SUB from an external environment.

It has been described hereinabove that the display panel 10 according to the disclosure may include an inorganic light emitting diode, but the disclosure is not limited thereto, and the display panel 10 according to the disclosure may be an organic light emitting display panel including an organic light emitting diode. The light emitting element layer of the display panel may include an organic layer including a hole injection/transport layer, a light emitting layer, and an electron injection/transport layer.

FIG. 6 is a schematic cross-sectional view taken along line VI-VI′ of FIG. 1. FIG. 7 is a schematic cross-sectional view taken along line VII-VII′ of FIG. 1. FIG. 6 illustrates a cross section of an area where the connection film 11 may be disposed, and FIG. 7 illustrates a cross section of an area where the connection film 11 may not be disposed.

Referring to FIGS. 6 and 7, the display device 1 may further include a cover member CM. The cover member CM may include a first cover part CM1 disposed on a surface (e.g., a first surface or an upper surface) SUBa of the substrate SUB and a second cover part CM2 disposed on a side surface SUBc of the substrate SUB.

Specifically, the substrate SUB may include a surface (e.g., first surface) SUBa, another surface (e.g., a second surface) SUBb, and a side surface SUBc. The second surface SUBb of the substrate SUB may be a surface opposite to first surface SUBa, and the side surface SUBc of the substrate SUB may extend from (e.g., connect) the first surface SUBa to another surface (e.g., second surface) SUBb of the substrate SUB to each other. The first surface SUBa of the substrate SUB may face a side (e.g., a first side) in the third direction DR3, and another surface (e.g., second surface) SUBb of the substrate SUB may face another side (e.g., second side) in the third direction DR3. A first surface SUBa of the substrate SUB may face the display surface of the display panel, and another surface (e.g., second surface) SUBb of the substrate SUB may face a surface opposite to the display surface of the display panel, but the disclosure is not limited thereto.

An end of the connection film 11 may be attached onto (e.g., to) a surface SUBa of the substrate SUB and be bent in the thickness direction (e.g., third direction DR3) along the side surface SUBc of the substrate SUB, and another end of the connection film 11 may be positioned below another surface (e.g., second surface) SUBb of the substrate SUB.

The cover member CM may be disposed on the connection film 11 and the substrate SUB. The cover member CM may be disposed on the connection film 11 in at least a partial area. The connection film 11 may be disposed between the cover member CM and the substrate SUB in an area in which the connection film 11 may be disposed. In an area where the connection film 11 may not be disposed, the cover member CM may be in direct contact with the side surface SUBc of the substrate SUB.

The cover member CM may cover the non-display area NDA of the display device 1. The cover member CM may cover the non-display area NDA in which the connection film 11 may be disposed. The cover member CM may cover the connection film 11 disposed in the non-display area NDA. The first cover part CM1 of the cover member CM may be disposed on a surface SUBa of the substrate SUB. The second cover part CM2 of the cover member CM may be disposed on the side surface SUBc of the substrate SUB, and may be disposed on a side surface of the first cover part CM1. The first cover part CM1 and the second cover part CM2 of the cover member CM may be formed integrally with each other, but are not limited thereto.

The cover member CM may not protrude upward. In other words, a surface (e.g., an upper surface) LFLa of the optical function layer LFL may be positioned at a height higher than a surface (e.g., an upper surface) CMla of the first cover part CM1, based on a surface SUBa or another surface SUBb of the substrate SUB. However, the disclosure is not limited thereto, and a surface (e.g., the upper surface) LFLa of the optical function layer LFL may be positioned at a height that may be substantially the same as that of a surface (e.g., the upper surface) CM1a of the first cover part CM1, based on a surface SUBa or another surface SUBb of the substrate SUB. Accordingly, it may be possible to suppress or prevent the cover member CM covering the connection film 11 from being recognized by the user, and it may be possible to suppress or prevent the user from sensing a sense of foreign matter. Therefore, a screen with improved immersion may be provided to the user.

The upper surface CM1a of the first cover part CM1 may be substantially flat. For example, the upper surface of the first cover part CM1 may be substantially flat regardless of the presence or absence of the connection film 11. The second cover part CM2 may have a convex shape toward the outside of the display device 1, but is not limited thereto.

The first cover part CM1 may have a first thickness TH1, and the second cover part CM2 may have a second thickness TH2. The first thickness TH1 may refer to an average thickness of the entire area of the first cover part CM1, and the second thickness TH2 may refer to an average thickness of the entire area of the second cover part CM2. The first thickness TH1 may refer to a width of the first cover part CM1 in the third direction DR3, and the second thickness TH2 may refer to a width of the second cover part CM2 in the second direction DR2. The first thickness TH1 may be greater than the second thickness TH2, but the disclosure is not limited thereto.

The cover member CM may include a curable resin.

The cover member CM may suppress or prevent permeation of external air, moisture, and the like, by covering the connection film 11 and the periphery of the connection film 11. The cover member CM may serve as a light blocking member. In other words, the cover member CM may block light leaked from the display device 1. The cover member CM may include a black dye or pigment, but is not limited thereto.

The display device 1 may further include a filler 13 disposed between the connection film 11 and the side surface SUBc of the substrate SUB. The filler 13 may include a resin, but is not limited thereto. The filler 13 may serve to block external air, moisture, and the like, that may permeate between a rear surface of the connection film 11 and the substrate SUB.

Hereinafter, a method of manufacturing a display device according to an embodiment will be described.

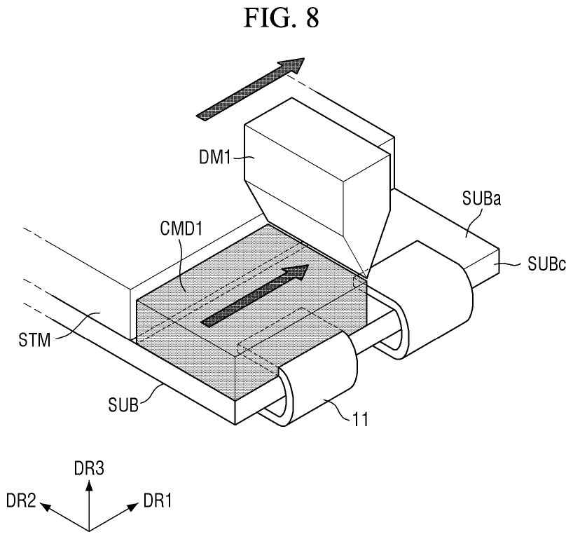

FIGS. 8 to 10 are schematic views for describing a method of manufacturing a display device according to an embodiment. FIGS. 8 to 10 illustrate a substrate SUB and a stacked member STM disposed on the substrate SUB. Here, the stacked member STM may include the circuit layer CCL (see FIG. 6), the light emitting element layer EML (see FIG. 6), the color control layer CWL (see FIG. 6), the encapsulation layer ENC (see FIG. 6), and the optical function layer LFL (see FIG. 6) that may be sequentially stacked on each other.

Referring to FIG. 8, a first cover member material layer (e.g., a first cover material layer) CMD1 may be applied onto an upper surface SUBa of the substrate SUB on which the connection film 11 may be disposed. In case that the first cover member material layer CMD1 is cured, it may become the first cover part CM1 of the cover member CM.

The first cover member material layer CMD1 may be applied through a first applying module DM1. The first applying module DM1 may include a slit nozzle, and the first cover member material layer CMD1 may be formed by slit lamination. An interval between the first applying module DM1 and the substrate SUB may be substantially the same as a thickness of the first cover member material layer CMD1 to be applied, and accordingly, the first cover member material layer CMD1 may be applied so that an upper surface thereof may be substantially flat. Accordingly, even though the connection film 11 may be disposed below the first cover member material layer CMD1, a step of the upper surface of the first cover member material layer CMD1 due to the connection film 11 may be suppressed or prevented.

The first cover member material layer CMD1 may be applied in a state in which the connection film 11 may be bent, but is not limited thereto.

The first applying module DM1 may apply the first cover member material layer CMD1 while moving from the another side (e.g., a second side) in the first direction DR1 to the side (e.g., first side) in the first direction DR1. The first cover member material layer CMD1 may cover a surface (e.g., first surface) SUBa of the substrate SUB exposed by the stacked member STM and the connection film 11. The first cover member material layer CMD1 may include a curable resin.

It has been illustrated in FIG. 8 that the first cover member material layer CMD1 may not overlap the stacked member STM, but the disclosure is not limited thereto, and the first cover member material layer CMD1 may be disposed to overlap at least one of the respective constituent layers included in the stacked member STM.

The first applying module DM1 may apply the first cover member material layer CMD1 while moving along the first direction DR1, and the first cover member material layer CMD1 may be applied while covering the upper surface SUBa of the substrate SUB and the connection film 11 disposed on the upper surface SUBa of the substrate SUB. Accordingly, even though the first cover member material layer CMD1 may be cured, the first cover member material layer CMD1 may be more readily removed.

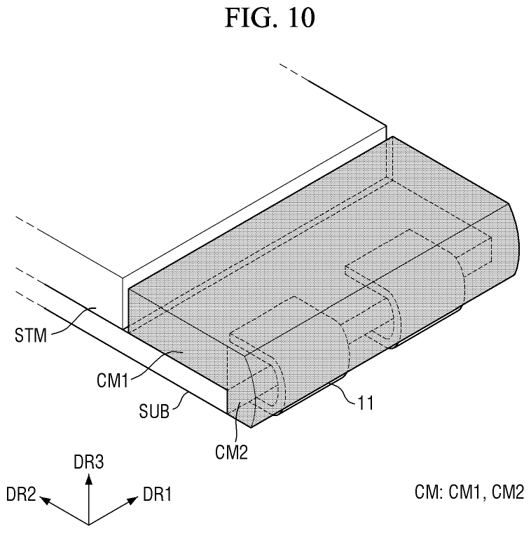

In other words, in case that the first cover member material layer CMD1 disposed on the connection film 11 or the first cover part CM1 (see FIG. 10) of the cover member CM (see FIG. 10) formed by curing the first cover member material layer CMD1 may be removed, the connection film 11 may be left on the substrate SUB without being removed. Therefore, even though an error or the like may occur in an application position of the first cover member material layer CMD1, the first cover member material layer CMD1 or the first cover part CM1 (see FIG. 10) of the cover member CM (see FIG. 10) may be removed without removing the connection film 11. Accordingly, even though the error or the like may occur in the application position of the first cover member material layer CMD1, the connection film 11 may be reused, a process cost may be reduced, and process efficiency may be improved.

In case that the first applying module DM1 includes the slit nozzle, the upper surface of the first cover member material layer CMD1 may be positioned at a height lower than a surface (e.g., an upper surface) of the uppermost layer of the stacked member STM, based on a surface SUBa or another surface SUBb of the substrate SUB. Therefore, even though the display panel 10 (see FIG. 6) may not include a separate encapsulation substrate, the height of the upper surface of the first cover member material layer CMD1 (e.g., the upper surface of the first cover part CM1 (see FIG. 10) may be lower than that of a surface (e.g., the upper surface) of the uppermost layer of the stacked member STM. Accordingly, the first cover part CM1 (see FIG. 10) may not protrude upward beyond a surface of the stacked member STM, and it may be possible to suppress or prevent the user from recognizing the first cover part CM1.

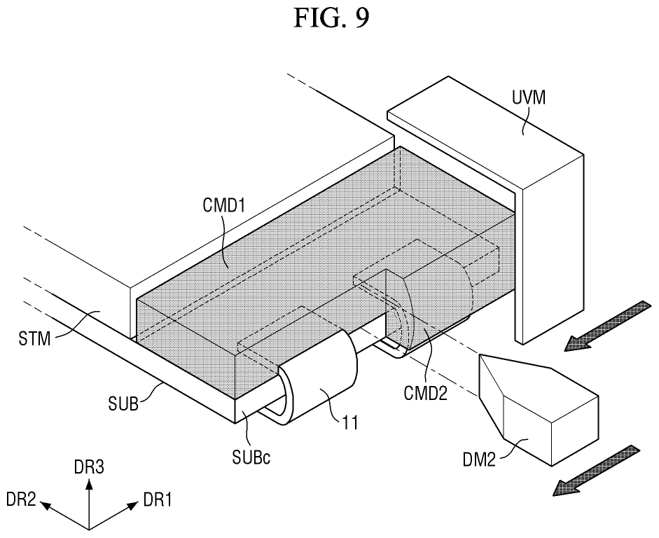

Referring to FIGS. 9 and 10, a second cover member material layer (e.g., a second cover material layer) CMD2 may be applied onto the side surface SUBc of the substrate SUB on which the connection film 11 may be disposed. In case that the second cover member material layer CMD2 is cured, it may become the second cover part CM2 of the cover member CM.

The second cover member material layer CMD2 may be applied through a second applying module DM2. The second applying module DM2 may include a jet valve. More delicate application may be possible, and accordingly, the second cover member material layer CMD2 may be applied onto the side surface SUBc of the substrate SUB even though a thickness of the substrate SUB may be thin. The second cover member material layer CMD2 may be applied in a state in which the connection film 11 may be bent. A process of applying the second cover member material layer CMD2 may be performed about 1 second after the application of the first cover member material layer CMD1 has been completed, but the disclosure is not limited thereto.

The second applying module DM2 may apply the second cover member material layer CMD2 while moving from the side (e.g., first side) in the first direction DR1 to the another side (e.g., second side) in the first direction DR1. The second cover member material layer CMD2 may cover the side surface SUBc of the substrate SUB and the connection film 11. The second cover member material layer CMD2 may include the same material as the first cover member material layer CMD1. For example, the second cover member material layer CMD2 may include a curable resin.

The second cover member material layer CMD2 may be applied before the first cover member material layer CMD1 may be cured. Accordingly, in a portion where the second cover member material layer CMD2 and the first cover member material layer CMD1 may be in direct contact with each other, the second cover member material layer CMD2 may be integrated with the first cover member material layer CMD1. Thereafter, even though the first cover member material layer CMD1 and the second cover member material layer CMD2 may be cured, a boundary may not be positioned between the first cover part CM1 and the second cover part CM2.

A curing module UVM may follow the second applying module DM2. In other words, the curing module UVM may move from the side (e.g., first side) in the first direction DR1 to another side (e.g., second side) in the first direction DR1, and may move along the second applying module DM2. The curing module UVM may move from a side (e.g., first side) in the first direction DR1 to another side (e.g., second side) in the first direction DR1, and cure the first cover member material layer CMD1 and the second cover member material layer CMD2.

Specifically, the curing module UVM may cover the upper surface of the first cover member material layer CMD1 and a side surface of the second cover member material layer CMD2. The curing module UVM may be disposed on a side (e.g., first side) of the first cover member material layer CMD1 in the third direction DR3 and be disposed on another side (e.g., second side) of the second cover member material layer CMD2 in the second direction DR2. The curing module UVM may be disposed to be spaced apart from the upper surface of the first cover member material layer CMD1 and the side surface of the second cover member material layer CMD2. The curing module UVM may emit ultraviolet (UV) light toward the first cover member material layer CMD1 and the second cover member material layer CMD2, and the first cover member material layer CMD1 and the second cover member material layer CMD2 may be cured by the UV light.

The second applying module DM2 may apply the second cover member material layer CMD2 while moving along the first direction DR1, and the second cover member material layer CMD1 may be applied while covering the side surface SUBc of the substrate SUB and the connection film 11 disposed on the side surface SUBc of the substrate SUB. Accordingly, even though the second cover member material layer CMD2 may be cured, the second cover member material layer CMD2 may be more readily removed.

In other words, in case that the second cover member material layer CMD2 disposed on the connection film 11 or the second cover part CM2 of the cover member CM formed by curing the second cover member material layer CMD2 is removed, the connection film 11 may be left on the substrate SUB without being removed. Therefore, even though an error or the like may occur in an application position of the second cover member material layer CMD2, the second cover member material layer CMD2 or the second cover part CM2 of the cover member CM may be removed without removing the connection film 11. Accordingly, even though the error or the like may occur in the application position of the second cover member material layer CMD2, the connection film 11 may be reused, a process cost may be reduced, and process efficiency may be improved.

The first applying module DM1 (see FIG. 8) and the second applying module DM2 may be connected to the same moving module together, but the disclosure is not limited thereto. Accordingly, the number of driving motors may be reduced, such that process efficiency may be improved, and a process cost may be reduced. The curing module UVM may be connected to a moving module different from the moving module to which the first applying module DM1 (see FIG. 8) and the second applying module DM2 may be connected, but the disclosure is not limited thereto.

Hereinafter, additional embodiments will be described. In the following embodiments, a description for the same or similar configurations as those of the embodiments described above will be omitted or simplified, and configurations different from those of the embodiments described above will be described.

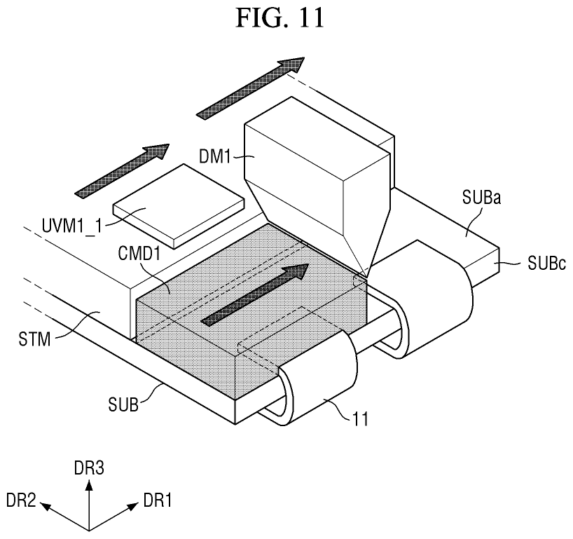

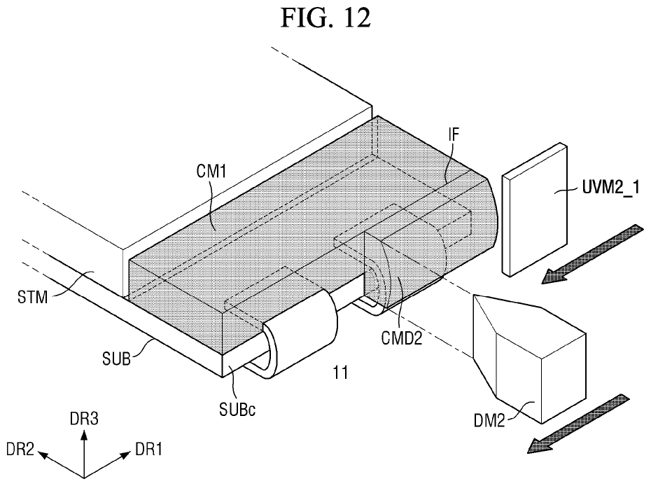

FIGS. 11 and 12 are schematic views for describing a method of manufacturing a display device according to another embodiment.

Referring to FIGS. 11 and 12, a method of manufacturing a display device according to an embodiment may be different from the method of manufacturing a display device according to embodiments described above with reference to FIGS. 8 to 10 at least in that the first cover member material layer CMD1 and the second cover member material layer CMD2 may be cured, respectively, by a first curing module UVM1_1 and a second curing module UVM2_1 separated from each other.

Specifically, the first curing module UVM1_1 may move from the another side (e.g., second side) in the first direction DR1 to the side (e.g., first side) in the first direction DR1 along the first applying module DM1. The first curing module UVM1_1 may cure the first cover member material layer CMD1 applied by the first applying module DM1. The first cover member material layer CMD1 may be applied, and may be cured by the first curing module UVM1_1 before the second cover member material layer CMD2 may be applied, such that the first cover part CM1 may be formed. The first applying module DM1 and the first curing module UVM1_1 may be connected to the same moving module together, but the disclosure is not limited thereto.

After the first cover member material layer CMD1 may be cured, the second cover member material layer CMD2 may be applied through the second applying module DM2. The second curing module UVM2_1 may move from a side (e.g., first side) in the first direction DR1 to another side (e.g., second side) in the first direction DR1 along the second applying module DM2. The second curing module UVM2_1 may cure the second cover member material layer CMD2 applied by the second applying module DM2. The second cover member material layer CMD2 may be applied, and may be cured by the second curing module UVM2 1, such that the second cover part CM2 (see FIG. 2) may be formed. The second applying module DM2 and the second curing module UVM2_1 may be connected to the same moving module together, but the disclosure is not limited thereto.

The second cover member material layer CMD2 may be applied after the first cover member material layer CMD1 may be cured, such that a boundary may be formed between the first cover part CM1 and the second cover member material layer CMD2. Even though the second cover member material layer CMD2 may be cured, a physical boundary may be positioned between the first cover part CM1 and the second cover part CM2 (see FIG. 10).

The second applying module DM2 and the second curing module UVM2_1 may not move in an direction opposite to a direction in which the first applying module DM1 and the first curing module UVM1_1 move, and may move in the same direction as the direction in which the first applying module DM1 and the first curing module UVM1_1 move.

Even though the first cover member material layer CMD1 and the second cover member material layer CMD2 may be cured, the first cover member material layer CMD1 and the second cover member material layer CMD2 may be more readily removed, and thus, the connection film 11 may be reused. The first curing module UVM1_1 and the second curing module UVM2_1 cure the first cover member material layer CMD1 and the second cover member material layer CMD2, respectively, and thus, more delicate curing may be possible, such that reliability of the display device may be improved.

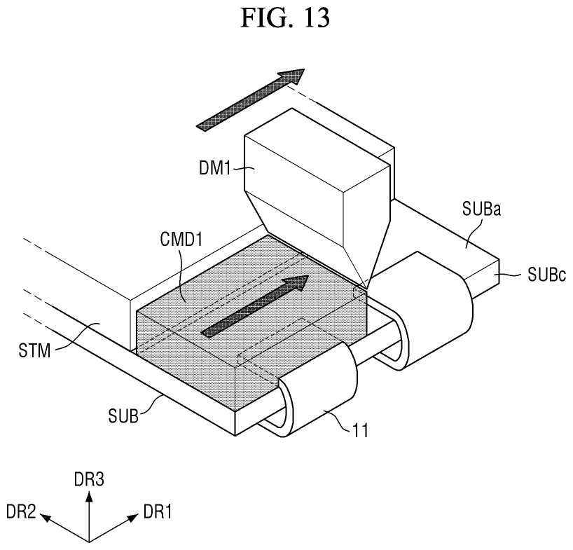

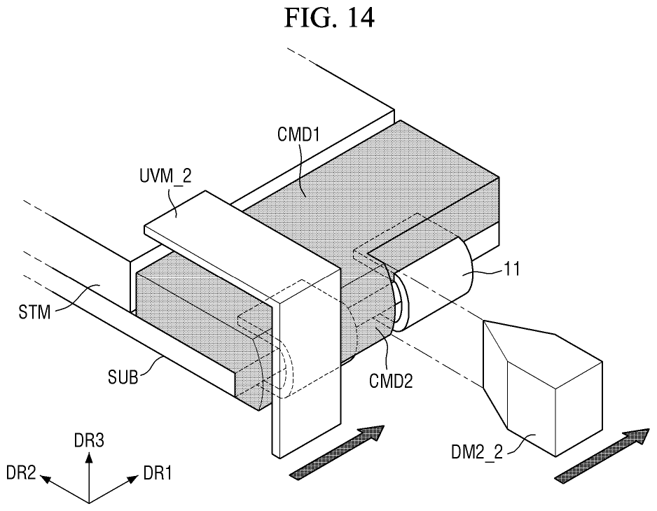

FIGS. 13 and 14 are schematic views for describing a method of manufacturing a display device according to still another embodiment.

Referring to FIGS. 13 and 14, a method of manufacturing a display device according to an embodiment may be different from the method of manufacturing a display device according to the embodiments described above with reference to FIGS. 8 to 10 at least in that a second applying module DM2_2 and a curing module UVM_2 may move in a direction that may be substantially the same as a direction in which the first applying module DM1 moves.

Specifically, the first applying module DM1 may apply the first cover member material layer CMD1 while moving from the another side (e.g., second side) in the first direction DR1 to a side (e.g., first side) in the first direction DR1. This may be substantially the same as embodiments described above with reference to FIG. 8. The second applying module DM2_2 may apply the second cover member material layer CMD2 while moving in the same direction (e.g., from another side in the first direction DR1 to a side in the first direction DR1) as the direction in which the first applying module DM1 has moved. The curing module UVM_2 cures the first cover member material layer CMD1 and the second cover member material layer CMD2 while following the second applying module DM2.

The first applying module DM1 and the second applying module DM2_2 may be connected to the same moving module together. The moving module may return to the origin again and move the second applying module DM2 from another side in the first direction DR1 to a side in the first direction DR1, after the first applying module DM1 has completed the application of the first cover member material layer CMD1.

Even though the first cover member material layer CMD1 and the second cover member material layer CMD2 may be cured, the first cover member material layer CMD1 and the second cover member material layer CMD2 may be more readily removed, and thus, the connection film 11 may be reused.

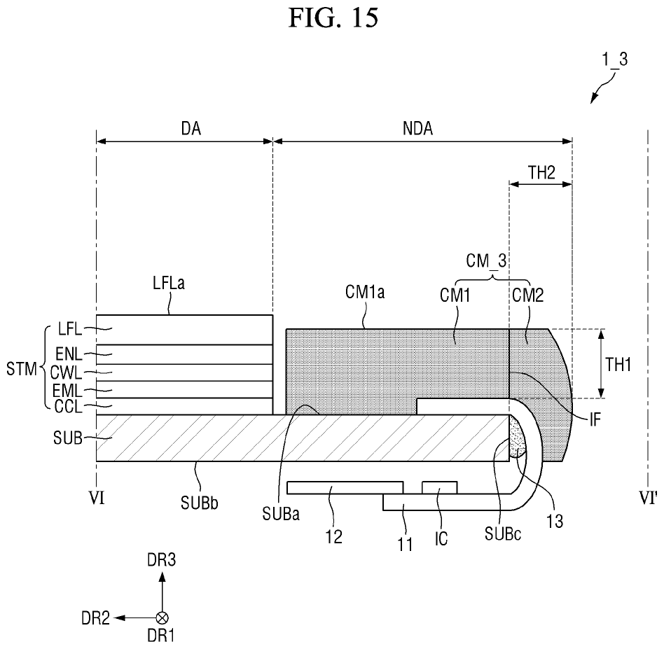

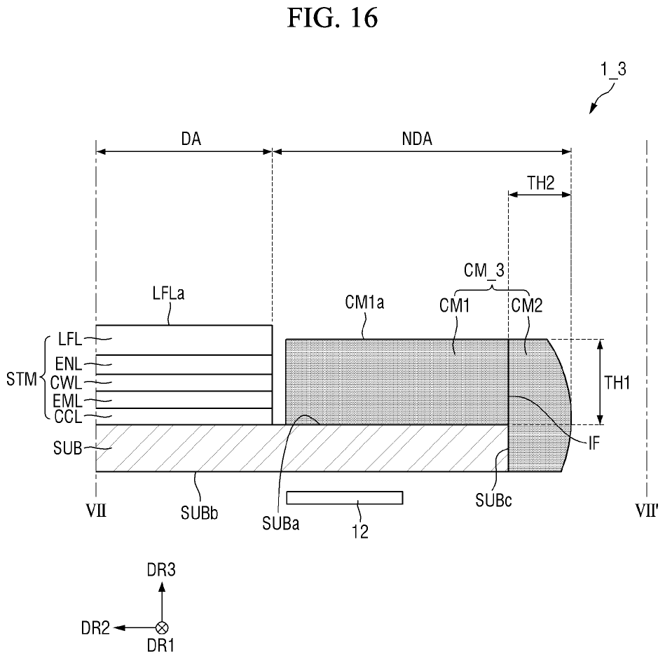

FIGS. 15 and 16 are schematic cross-sectional views of a display device according to another embodiment. FIG. 15 illustrates a cross section of an area where the connection film 11 may be disposed, and FIG. 16 illustrates a cross section of an area where the connection film 11 may not be disposed.

Referring to FIGS. 15 and 16, a display device 1_3 according to an embodiment may be different from the display device according to embodiments described above with reference to FIGS. 6 and 7 at least in that an interface IF may be positioned between a first cover part CM1 and a second cover part CM2 of a cover member CM_3. This may be due to the fact that the first cover part CM1 and the second cover part CM2 may be formed by different processes. For example, as illustrated in FIGS. 11 and 12, in case that the second cover part CM2 is formed by applying and curing the second cover member material layer CMD2 (see FIG. 12) after the first cover part CM1 may be formed by curing the first cover member material layer CMD1 (see FIG. 11), the interface IF may be formed between the first cover part CM1 and the second cover part CM2.

The cover member CM may be more readily removed, such that the connection film 11 may be reused.

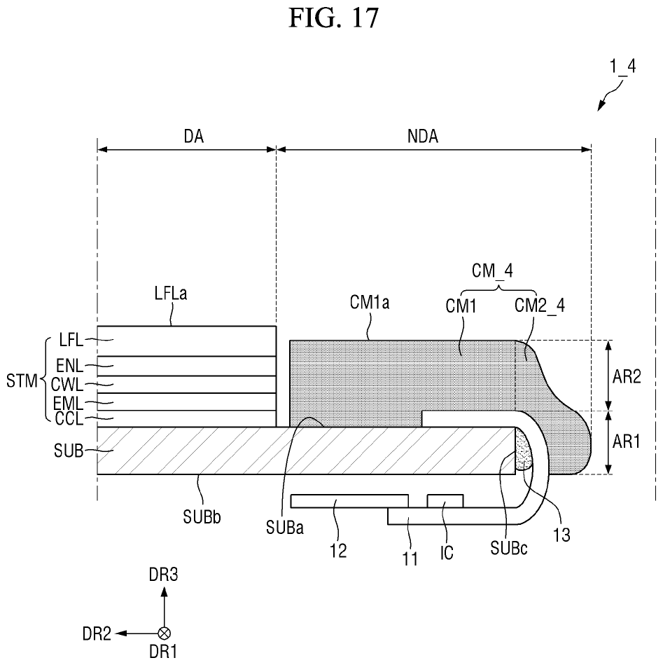

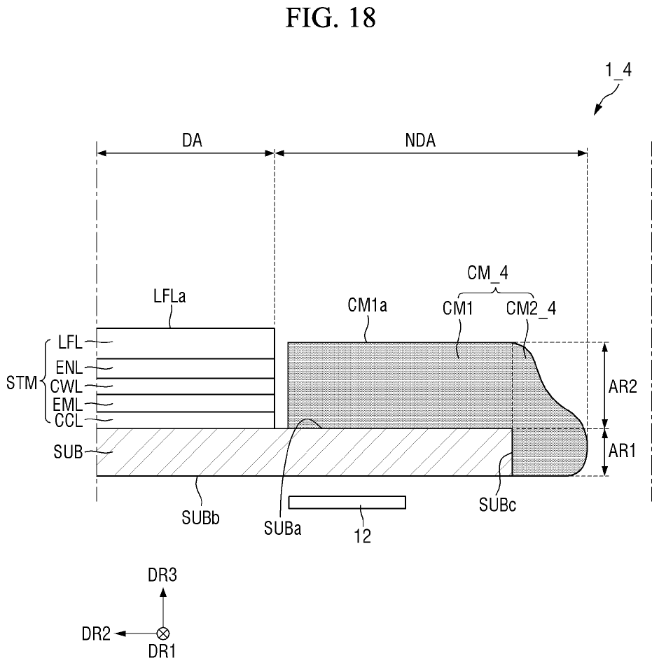

FIGS. 17 and 18 are schematic cross-sectional views of a display device according to still another embodiment. FIG. 17 illustrates a cross section of an area where the connection film 11 may be disposed, and FIG. 18 illustrates a cross section of an area where the connection film 11 may not be disposed.

Referring to FIGS. 17 and 18, a display device 1_4 according to an embodiment may be different from the display device according to embodiments described above with reference to FIGS. 6 and 7 at least in that a second cover part CM2_4 of the cover member CM_4 may have a thickness that substantially increases toward a lower side (e.g., the another side) in the thickness direction (e.g., third direction DR3). This may be due to the fact that a time interval exists from when the second cover member material layer CMD2 (see FIG. 9) has been applied onto the side surface SUBc of the substrate SUB until the second cover member material layer CMD2 may be cured. In other words, in case that the second cover member material layer CMD2 (see FIG. 9) is applied onto the side surface SUBc of the substrate SUB, the second cover member material layer CMD2 (see FIG. 9) including the resin may be affected by gravity in the thickness direction (e.g., third direction DR3) until it may be cured, and may move downward. Therefore, the second cover part CM2_4 may have the thickness that substantially increases toward the lower side.

The second cover part CM2_4 may be bisected in the third direction DR3 and may include a first area AR1 disposed on a lower side and a second area AR2 disposed on an upper side of the first area AR1, but the disclosure is not limited thereto. A thickness of the first area AR1 (e.g., a width of the first area AR1 in the second direction DR2) may be greater than a thickness of the second area AR2 (e.g., a width of the second area AR2 in the second direction DR2). Here, the thickness of the first area AR1 (e.g., the width of the first area AR1 in the second direction DR2) may refer to an average thickness of the entire area of the first area AR1, and the thickness of the second area AR2 (e.g., the width of the second area AR2 in the second direction DR2) may refer to an average thickness of the entire area of the second area AR2.

The cover member CM may be more readily removed, such that the connection film 11 may be reused.

Although embodiments of the disclosure have been disclosed for illustrative purposes, those skilled in the art will appreciate that various modifications, additions and substitutions are possible, without departing from the scope and spirit of the disclosure.

What is claimed is:

1. A display device comprising:
a substrate including:
a first surface;
a second surface opposite to the first surface; and
a side surface extending from the first surface to the second surface;
a film having an end attached to the first surface of the substrate and bent from the end to cover the side surface of the substrate; and
a cover member including:
a first cover part disposed on the first surface of the substrate; and
a second cover part disposed on the side surface of the substrate, wherein
the film is disposed between the first surface of the substrate and the first cover part and between the side surface of the substrate and the second cover part, and
the second cover part has an outwardly convex shape.

2. The display device of claim 1, wherein
the first cover part has a first thickness, and
the second cover part has a second thickness smaller than the first thickness.

3. The display device of claim 1, wherein
the second cover part is disposed on a side surface of the first cover part, and
the first cover part and the second cover part are integral with each other.

4. The display device of claim 1, wherein
the second cover part is disposed on a side surface of the first cover part, and
the cover member further includes an interface disposed between the first cover part and the second cover part.

5. The display device of claim 1, further comprising a filler disposed between the film and the side surface of the substrate.

6. The display device of claim 1, wherein
the second cover part is bisected in a thickness direction to include a first area and a second area that are sequentially stacked on each other, and
the first area has a thickness greater than a thickness of the second area.

7. The display device of claim 1, further comprising:
a display area displaying a screen; and
a non-display area adjacent to the display area,
wherein the film and the cover member are disposed in the non-display area.

8. The display device of claim 7, further comprising pixels disposed in the display area,
wherein each of the pixels includes an inorganic light emitting element.

9. A display device comprising:
a substrate including:
a first surface;
a second surface opposite to the first surface; and
a side surface extending from the first surface to the second surface;
a film having an end attached to the first surface of the substrate and bent from the end to cover the side surface of the substrate; and
a cover member including:
a first cover part disposed on the first surface of the substrate; and
a second cover part disposed on the side surface of the substrate, wherein
the first cover part has a first thickness, and
the second cover part has a second thickness smaller than the first thickness.

10. The display device of claim 9, wherein
the second cover part is disposed on a side surface of the first cover part, and
the cover member further includes an interface disposed between the first cover part and the second cover part.

11. The display device of claim 9, wherein
the second cover part is bisected in a thickness direction to include a first area and a second area that are sequentially stacked on each other, and
the first area has a thickness greater than a thickness of the second area.

12. A method of manufacturing a display device, comprising:
bending a film attached to a first surface of a substrate toward a lower surface of the substrate along a side surface of the substrate;
applying a first cover material layer onto the first surface of the substrate and the film; and
applying a second cover material layer onto the side surface of the substrate and the film.

13. The method of manufacturing a display device of claim 12, further comprising, after the applying of the second cover material layer, curing the first cover material layer and the second cover material layer.

14. The method of manufacturing a display device of claim 13, wherein the curing of the first cover material layer and the second cover material layer is performed by ultraviolet (UV) light.

15. The method of manufacturing a display device of claim 12, further comprising:
curing the first cover material layer, after the applying of the first cover material layer and before the applying of the second cover material layer; and
curing the second cover material layer, after the applying of the second cover material layer.

16. The method of manufacturing a display device of claim 15, wherein
the curing of the first cover material layer is performed by a first curing module, and
the curing of the second cover material layer is performed by a second curing module.

17. The method of manufacturing a display device of claim 12, wherein
the first cover material layer is applied by a first applying module, and
the first applying module moves from a second side in a first direction to a first side in the first direction.

18. The method of manufacturing a display device of claim 17, wherein
the second cover material layer is applied by a second applying module, and
the second applying module moves from the first side in the first direction to the second side in the first direction.

19. The method of manufacturing a display device of claim 18, further comprising, after the applying of the second cover material layer, curing the first cover material layer and the second cover material layer, wherein
the curing of the first cover material layer and the second cover material layer is performed by a curing module, and
the curing module moves from the first side in the first direction to the second side in the first direction.

20. The method of manufacturing a display device of claim 17, wherein
the second cover material layer is applied by a second applying module, and
the second applying module moves from the first side in the first direction to the second side in the first direction.
